(19) United States
(12) Patent Application Publication
(10) Pub. No.: US 2015/0228635 A1
(43) Pub. Date: Aug. 13, 2015

(54) INTEGRATED CIRCUIT DEVICE HAVING SUPPORTS FOR USE IN A MULTI-DIMENSIONAL DIE STACK

(71) Applicant: GLOBALFOUNDRIES Inc., Grand Cayman (KY)

(72) Inventor: Tak M. Mak, Union City, CA (US)

(73) Assignee: GLOBALFOUNDRIES Inc., Grand Cayman (KY)

(21) Appl. No.: 14/176,528

(22) Filed: Feb. 10, 2014

(51) Int. Cl. H01L 25/18; H01L 23/00; H01L 23/50; H01L 25/00

(52) U.S. Cl. CPC H01L 25/18; H01L 25/50; H01L 23/562; H01L 23/50

(57) ABSTRACT

Provided is an integrated circuit (IC) device having a support structure for use in a multi-dimensional (e.g., 3-D) die stack. The IC device includes a first chip (e.g., a memory die) positioned over a second chip (e.g., a logic layer), and a set of support structures between the memory die and the logic layer, wherein the set of support structures is arranged so as to radiate from a center of the memory die. In one approach, the set of support structures comprises two linear arrays each including a plurality of support members coupled to the memory die, the two linear arrays arranged in a standardized diagonal crossing configuration to provide increased stability between the memory die and the logic layer. In an exemplary embodiment, the set of support structures is connected to a power grid to help deliver power to circuitry of the memory die.

### BACKGROUND

1. Technical Field

This present disclosure relates generally to integrated circuits (IC) and, more particularly, to stacking multiple chips in a multi-dimensional IC structure.

2. Related Art

The dynamic random access memory (DRAM) industry has been trying to resolve issues related to high-performance DRAM that is used in high-end application processors such as smartphone or tablet processors. Today, the industry is using low power (LP) double-data-rate (DDR) DRAM such as LP-DDR2 and DDR3 DRAM. The Joint Electron Devices Engineering Council (JEDEC) is presently discussing LP-DDR3 and DDR4 as well as wide I/O DRAM. Wide I/O (WIO) DRAM address bandwidth challenges with a lower data rate (e.g., 200 Mbps to 800 Mbps) but wider (e.g., 512 bits) IO bus. In order for the system-on-chip (SoC) to talk to the WIO DRAM, the WIO bus was brought to the backside of the SoC with through silicon via (TSV) technology and finished with a microbump on top of the silicon backside. The WIO DRAM is then bonded to these microbumps, which connects the SoC through the TSV. However, when the DRAM dies are placed over the SoC during bonding, it may tilt and result in poor bonding or an open bond. However, custom support bumps currently used by manufacturers negate standardization as DRAM die size varies. This is especially problematic, for example, when the DRAM die overhangs the SoC, as the DRAM die size is usually larger than the SoC customized support features that match DRAM and, once fixed, the support features are not adaptable to multiple suppliers.

### SUMMARY

In general, an integrated circuit (IC) device having a support structure for use in a three-dimensional (3-D) die stack is disclosed. Specifically, the IC device includes a first chip (e.g., a memory die) positioned over a second chip (e.g., a logic layer), and a set of support structures between the memory die and the logic layer, wherein the set of support structures is arranged so as to radiate from a center of the memory die. In one approach, the set of support structures comprises two linear arrays each including a plurality of support members coupled to the memory die, the two linear arrays configured in a standardized diagonal crossing arrangement to provide increased stability between the memory die and the logic layer. In an exemplary embodiment, the set of support structures is connected to a power grid to help deliver power to circuitry of the memory die.

One aspect of the present invention includes an integrated circuit (IC) device, comprising: a set of support structures between at least two chips of the IC device, the set of support structures radiating uniformly from a center of the memory die.

Another aspect of the present invention includes an integrated circuit (IC) device having a support structure for use in a multi-dimensional die stack, the IC device comprising: a memory die coupled to a system-on-chip (SoC); and a set of support structures between the memory die and the SoC, the set of support structures radiating uniformly from a center of the memory die.

Yet another aspect of the present invention includes a method of forming an integrated circuit (IC) device, the method comprising: providing a first chip positioned over a second chip; forming a set of support structures on a surface of the first chip, wherein the set of support structures is configured to radiate from a center of the first chip; and coupling the set of support structures to the second chip.

### BRIEF DESCRIPTION OF THE DRAWINGS

These and other features of this invention will be more readily understood from the following detailed description of the various aspects of the invention taken in conjunction with the accompanying drawings in which:

FIG. 1 shows a top view of a memory die of an IC device according to illustrative embodiments;

FIG. 2 shows a top view of the memory die and a logic layer of the IC device according to illustrative embodiments;

FIGS. 3A-3F show top views of various support structure configurations according to illustrative embodiments;

FIG. 4 shows a side cross sectional view of a support element according to illustrative embodiments;

FIG. 5 shows a top view of a power grid according to illustrative embodiments; and

FIG. 6 shows a process flow for providing an IC device having a support structure for use in a multi-dimensional die stack according to illustrative embodiments.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines, which would otherwise be visible in a “true” cross-sectional view, for illustrative clarity. Furthermore, for clarity, some reference numbers may be omitted in certain drawings.

### DETAILED DESCRIPTION

Exemplary embodiments will now be described more fully herein with reference to the accompanying drawings, in which exemplary embodiments are shown. It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art.

The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure, e.g., a first layer, is present on a second element, such as a second structure, e.g. a second layer, wherein intervening elements, such as an interface structure, e.g. interface layer, may be present between the first element and the second element.

As mentioned above, approaches herein provide an IC device having a support structure for use in 3-D die stack. Specifically, the IC device includes a first chip (e.g., a memory die) positioned over a second chip (e.g., a logic layer), and a set of support structures between the memory die and the logic layer, wherein the set of support structures is arranged so as to radiate from a center of the memory die. In one approach, the set of support structures comprises two linear arrays each including a plurality of support members coupled to the memory die, the two linear arrays arranged in a standardized diagonal crossing configuration to provide increased stability between the memory die and the logic layer. In an exemplary embodiment, the set of support structures is connected to a power grid to help deliver power to circuitry of the memory die.

It will be appreciated that portions of the IC device structure are formed using well-known techniques and process steps that will not be described in detail here. Moreover, the various tasks and process steps described herein may be incorporated into a more comprehensive procedure or process having additional steps or functionality not described in detail herein. In particular, various steps in the manufacture of semiconductor based transistors are well known and so, in the interest of brevity, many conventional steps will only be mentioned briefly herein or will be omitted entirely without providing the well-known process details.

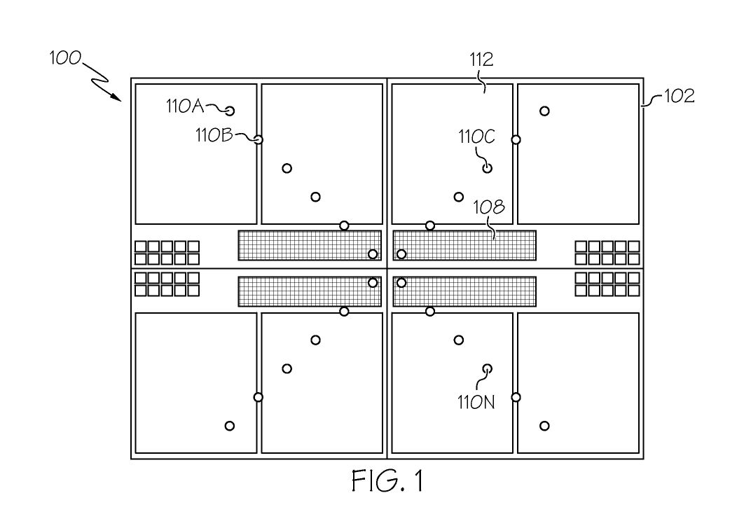

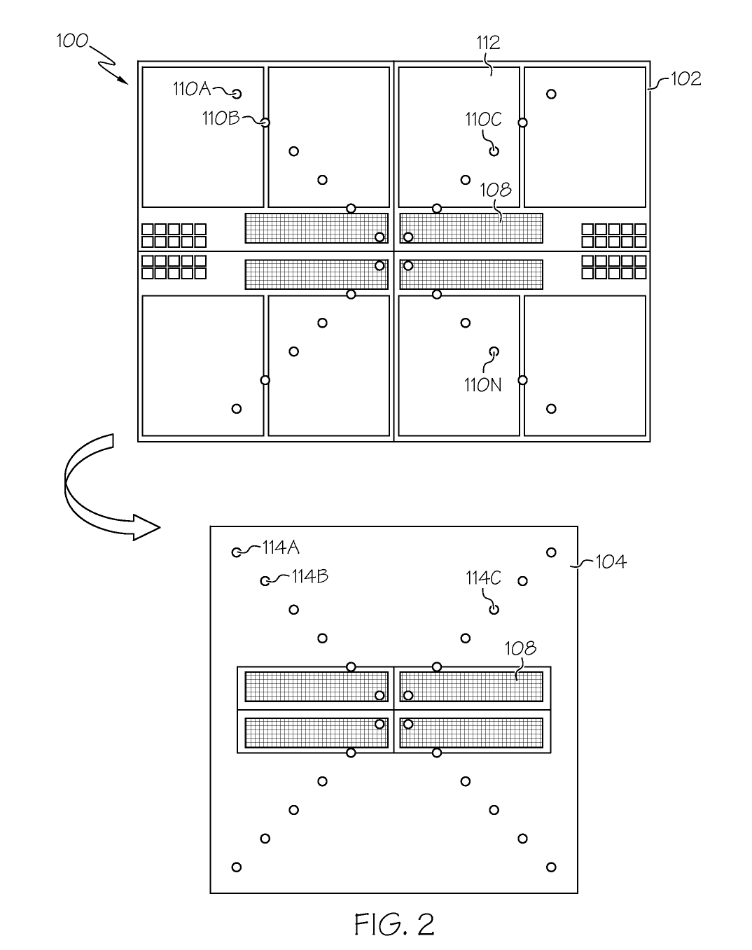

With reference now to the figures, FIGS. 1-2 show top views of a device 100 (e.g., a IC device) having multiple chips stacked in a 3-D structure. For the purpose of explanation, device 100 will be herein described as an IC device including a memory die 102, which is positioned over a logic layer 104 (FIG. 2) during construction of IC device 100. In an exemplary embodiment, logic layer 104 is a system-on-chip (SoC), i.e., an integrated chip on a system level. However, it will be appreciated that the invention is not limited to this specific configuration and, instead, may apply to virtually any stacked multi-dimensional chip structure in which it is desirable that the dies remain co-planar (i.e., parallel) to each other.

System-on-chip 104 may include a computational element (e.g., a microprocessor, a digital signal processor, an image processor, etc.) as well as a memory, a logic circuit, an input/output circuit, and other connection circuits. A system-on-chip is a single chip integrated with IC components, which have different functions and are otherwise scattered in different chips. Therefore, a system-on-chip can be regarded as a single system having multiple functions.

In exemplary embodiments, memory die 102 comprises DRAM, and a micro-pillar array 108 in a central portion thereof. IC device 100 further comprises a set of support structures 110A-N formed on a surface 112 of memory die 102, wherein support structures 110A-N are arranged in a configuration that radiates from a center of memory die 102. More specifically, set of support structures 110A-N comprises two linear arrays arranged in a diagonal crossing pattern, e.g., substantially perpendicular to each other, as shown. Each of support structures 110A-N within each linear array is uniformly spaced from an adjacent support structure (e.g., 0.5 mm). As such, support structures 110A-N are provided in a standardized, repeatable configuration, which can be adopted and implemented across memory dies and logic layers from multiple manufacturers.

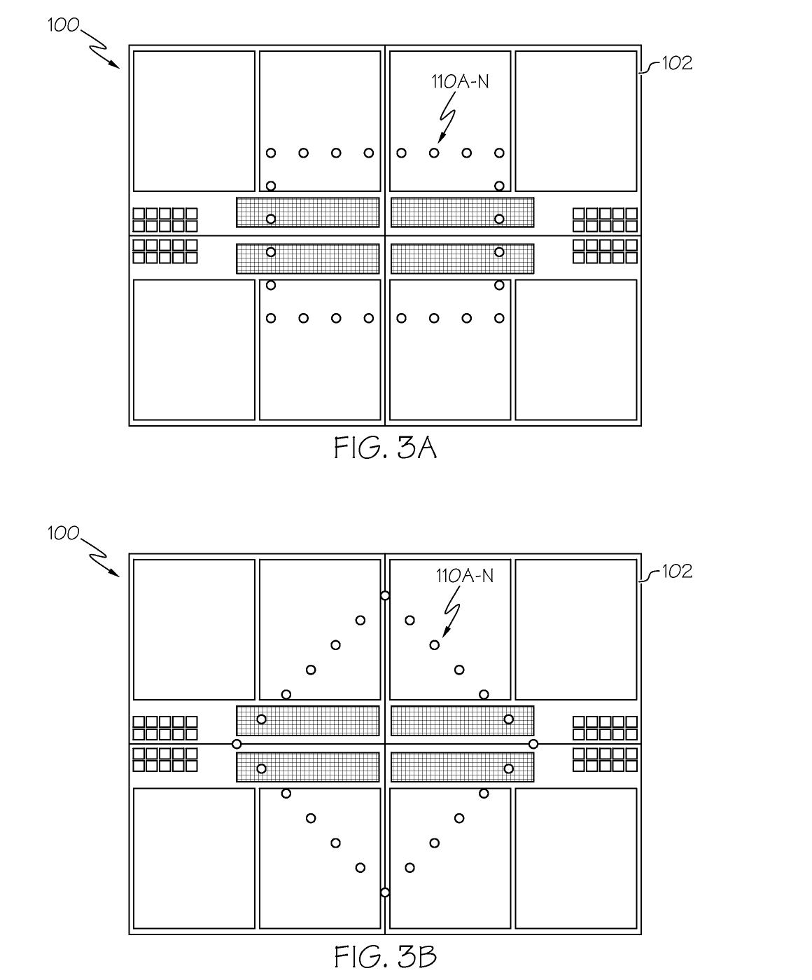

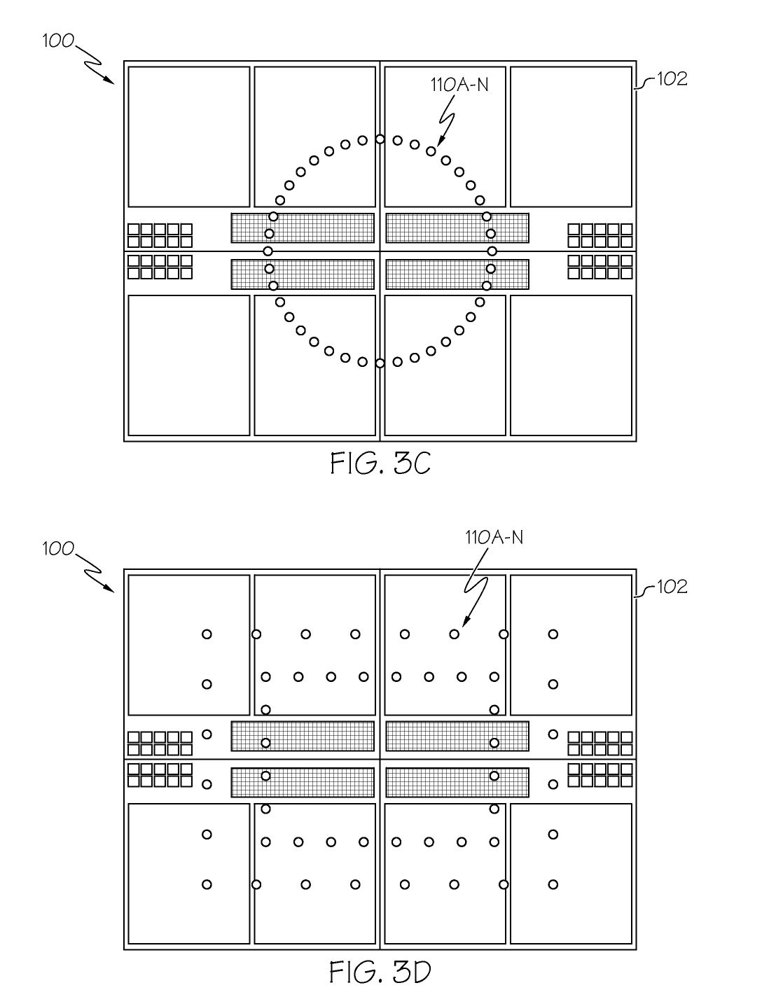

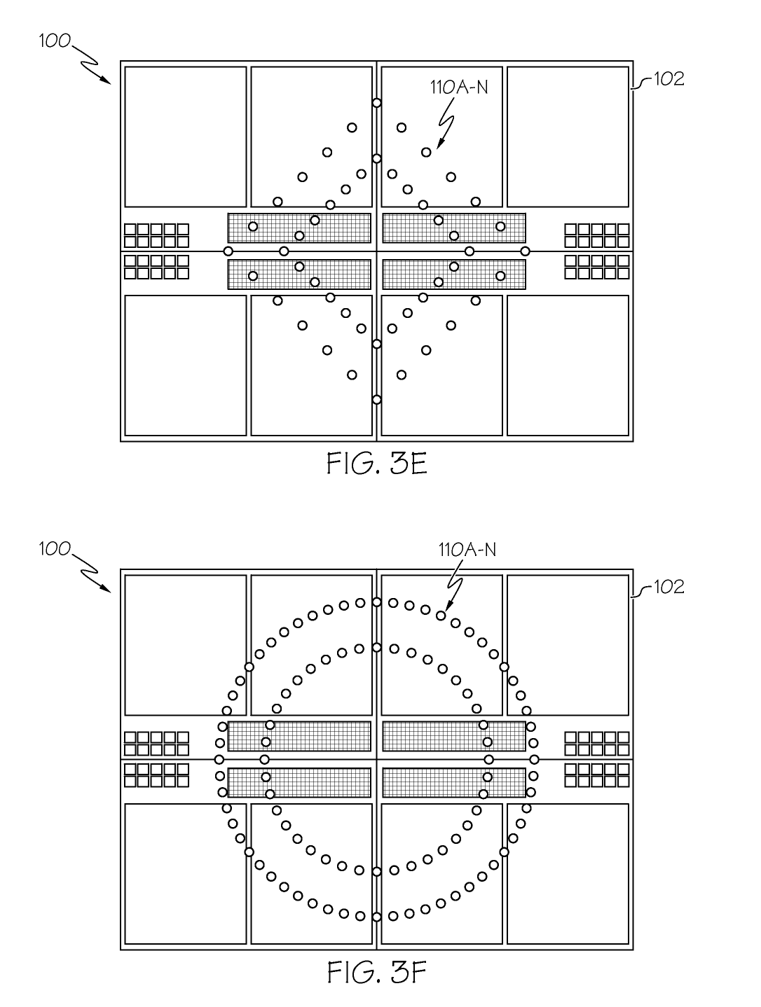

It will be appreciated that the invention is not limited to the specific configuration of support structures shown in FIGS. 1-2. Instead, a variety of configurations are possible within the scope of the invention, including, for example, a substantially rectangular configuration as shown in FIG. 3A, a substantially diamond shaped configuration as shown in FIG. 3B, a substantially circular shaped configuration as shown in FIG. 3C, a double rectangular shaped configuration as shown in FIG. 3D, a double diamond shaped configuration as shown in FIG. 3E, a double circular shaped configuration as shown in FIG. 3F, or any other suitable configuration.

Furthermore, it will be appreciated that there are many possible geometric configurations for support structures 110A-N. For instance, although support structures 110A-N are depicted herein as having a substantially cylindrical shape, support structures 110A-N may alternatively be configured as pillars having a rectangular cross-section, pillars having a triangular cross-section, truncated pyramids, truncated cones, truncated curved cones, elongated strips, cylinders, and any other suitable shape.

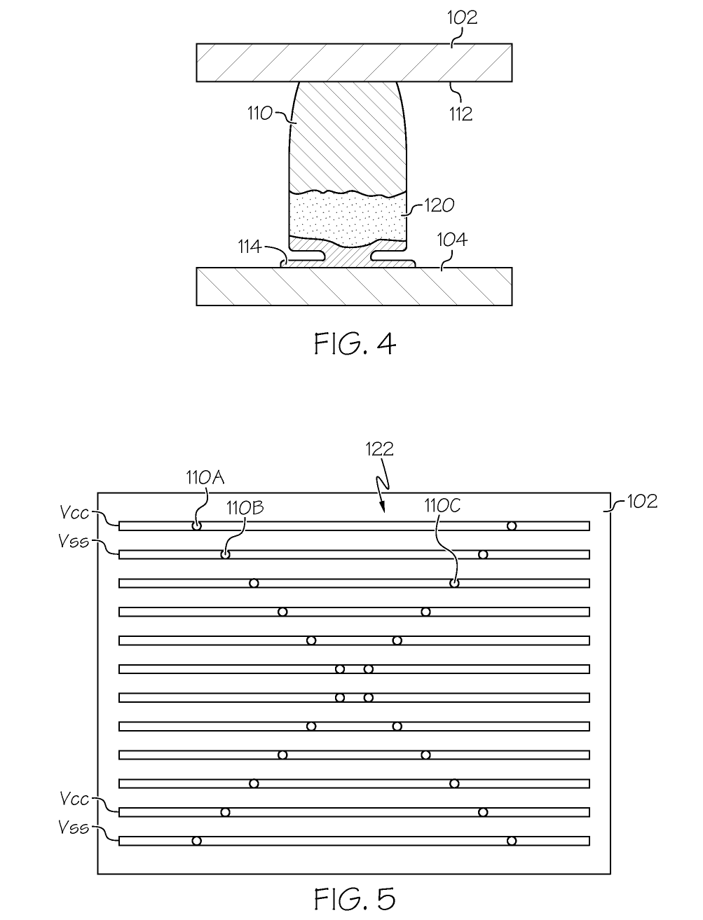

As shown in FIGS. 2 and 4, logic layer 104 comprises a plurality of landing pads 114A-N formed thereon and configured to receive one or more of support structures 110A-N when memory die 102 is placed on logic layer 104. In an exemplary embodiment, the number of support structures and landing pads is the same. However, this is not required so long as the position and spacing of those support structures and landing pads that are present line up. In the case that no landing pad is present on SoC, that particular support structure will be open and covered by underfill, which will protect any exposed metal. In another embodiment, those support structures falling into micro-pillar array 108 can be deleted. Furthermore, it will be appreciated that the number and spacing of support structures 110A-N and landing pads 114A-N is just for illustration purposes and, in reality, will be more numerous and closely spaced.

As shown in the side view of FIG. 4, support structure 110 comprises a pillar-shaped support member connected to surface 112 of memory die 102 on one end, and to landing pad 114 on the other end. In an exemplary embodiment, support structure 110 and landing pad 114 comprise copper, and are coupled by a tin-silver (SnAg) solder 120 using IMC (intermetallic compound) formation. In another embodiment, support structure 110 and IC device 100 can be formed by thermo-compression Cu—Cu bonding.

Conventional flip-chip reflow solder bonding techniques can be used to align and then fuse these solder connections between memory die 102 and landing pad 114 by melting solder bumps to form support structures 110A-N, which provide electrical and mechanical connection between the chips. Specifically, the following non-limiting processing steps may be used.
1. Logic layer 104 is patterned with copper contact pads using, e.g., bump plating techniques to form landing pads 114A-N.
2. Memory die 102 is patterned on one side with copper posts/pillars 110 capped with SnAg 120. Pre-bond reflow can be performed to round the SnAg cap, if desired. The back side of memory die 102 is patterned with copper pads (not shown), which can be connected to chip circuitry (with, for example, “through-silicon vias” (TSV)).
3. Atmospheric plasma treatment removes oxide from the copper pads of logic layer 104 and then passivates them against re-oxidation.
4. Atmospheric plasma treatment removes oxide from the SnAg 120 on memory die 102 and then passivates them against re-oxidation.
5. Logic layer 104 and memory die 102 are placed face-to-face (SnAg 120 to copper landing pad 114) in a flip-chip bonder and aligned. Appropriate force (e.g., 0.0068 gf/μm²) is applied and the assembly is heated, e.g., to 180° C., and the softened SnAg bumps compress into the copper pads. SnAg-copper adhesion is therefore achieved.
6. The bonded assembly is removed from the flip-chip bonder and is treated with atmospheric plasma on the face-up side logic layer 102 (copper pads).
7. This procedure can be repeated for each subsequent chip to be stacked on the 3-D structure. Following attachment of the final chip in the stack, the whole assembly can be reflowed, if desired, although reflow is not typically required.

In an exemplary embodiment, support structures 110A-N are connected to and communicate with a power grid 122, as shown in FIG. 5. Specifically, support structures 110A-N are coupled to Vcc and Vss (Gnd) of power grid 122 to deliver power to DRAM circuitry (not specifically shown), including in the corner regions of memory die 102, which is an improvement over existing DRAM routing.

In various embodiments, design tools can be provided and configured to create the datasets used to form the IC device as described herein. For example, data sets can be created to: provide a memory die positioned over a logic layer; form a set of support structures on a surface of the memory die, wherein the set of support structures is arranged as a plurality of linear arrays radiating uniformly from a center of the memory die; and couple the set of support structures to the logic layer. Such design tools can include a collection of one or more modules and can also be comprised of hardware, software, or a combination thereof. Thus, for example, a tool can be a collection of one or more software modules, hardware modules, software/hardware modules, or any combination or permutation thereof.

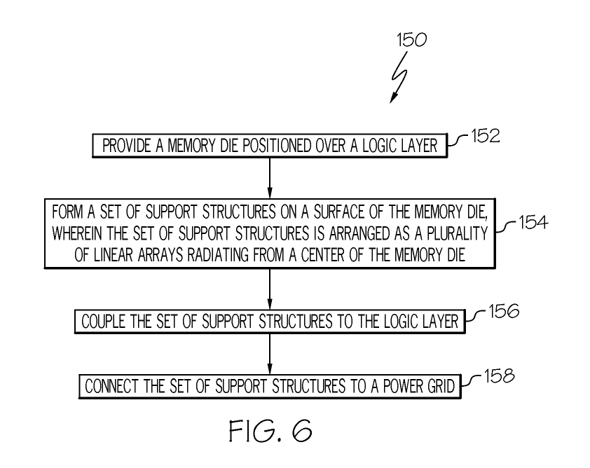

The software/hardware modules of the tool may be configured to perform a process 150, as shown in FIG. 6. Process 150 includes providing a memory die positioned over a logic layer (152), forming a set of support structures on a surface of the memory die, wherein the set of support structures is arranged as a plurality of linear arrays radiating uniformly from a center of the memory die (154), coupling the set of support structures to the logic layer (156), and connecting the set of support structures to a power grid (158).

As another example, the tool can be a computing device or other appliance on which software runs or in which hardware is implemented. As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

It is apparent that there has been provided approaches for providing an IC device having a support structure for use in a 3-D die stack. While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

1. An integrated circuit (IC) device, comprising:
a set of support structures between at least a first and second chip of the IC device, the first chip comprising a memory die, and the set of support structures radiating uniformly from a center of the memory die, and
a power grid formed on and extending over a substantial portion of the memory die, a first portion of the power grid being adapted for being coupled to a first voltage source, and a first plurality of the support structures are coupled to the first portion of the power grid at spaced apart locations to receive the first voltage source.

2. The IC device according to claim 1, wherein the first chip of the IC device comprises a memory die, and wherein the second chip of the IC device comprises a logic layer.

3. The IC device according to claim 2, the set of support structures comprising:
a plurality of support members coupled to the power grid of the memory die, the plurality of support members arranged as a plurality of linear arrays radiating uniformly from the center of the memory die; and
a plurality of landing pads coupled to the logic layer for receiving one or more of the plurality of support members.

4. The IC device according to claim 3, wherein the set of support structures comprises two linear arrays arranged in a substantially diagonal crossing pattern.

5. The IC device according to claim 4, wherein the two linear arrays are arranged substantially perpendicular to each other.

6. The IC device according to claim 2, wherein the memory die comprises a dynamic random access memory (DRAM) device.

7. The IC device according to claim 1, wherein a second portion of the power grid is adapted for being coupled to a second voltage source and a second plurality of the support structures are coupled to the second portion of the power grid at spaced apart locations to receive the second voltage source.

8. An integrated circuit (IC) device having a support structure for use in a multi-dimensional die stack, the IC device comprising:
a memory die coupled to a system-on-chip (SoC);
a set of support structures between the memory die and the SoC, the set of support structures radiating uniformly from a center of the memory die, and
a power grid formed on and extending over a substantial portion of the memory die, a first portion of the power grid being adapted for being coupled to a first voltage source, and a first plurality of the support structures are coupled to the first portion of the power grid at spaced apart locations to receive the first voltage source.

9. The IC device according to claim 8, the set of support structures comprising:
a plurality of support members coupled to the memory die, the plurality of support members arranged as a plurality of linear arrays radiating uniformly from the center of the memory die; and
a plurality of landing pads coupled to the SoC for receiving one or more of the plurality of support members.

10. The IC device according to claim 9, wherein the set of support structures comprises two linear arrays arranged in a substantially diagonal crossing pattern.

11. The IC device according to claim 10, wherein the two linear arrays are arranged substantially perpendicular to each other.

12. The IC device according to claim 9, wherein each of the set of support structures within each linear array is uniformly spaced from an adjacent support structure of the set of support structures.

13. The IC device according to claim 8, wherein the memory die comprises a dynamic random access memory (DRAM) device.

14. The IC device according to claim 8, wherein a second portion of the power grid is adapted for being coupled to a second voltage source and a second plurality of the support structures are coupled to the second portion of the power grid at spaced apart locations to receive the second voltage source.

15. A method of forming an integrated circuit (IC) device, the method comprising:
providing a first chip positioned over a second chip;
forming a power grid on the first chip;
coupling a first portion of the power grid to a first voltage source;
forming a set of support structures on a surface of the first chip, wherein the set of support structures is configured to radiate from a center of the first chip,
coupling a first plurality of the support structures to the first portion of the power grid at spaced apart locations to receive the first voltage source; and
coupling the set of support structures to the second chip.

16. The method according to claim 15, wherein the first chip comprises a memory die, and wherein the second chip comprises a logic layer.

17. The method according to claim 16, the forming the set of support structures comprising:
forming a plurality of support members coupled to the memory die; and
forming a plurality of landing pads coupled to the logic layer for receiving one or more of the plurality of pillar-shaped support members.

18. The method according to claim 17, further comprising:
coupling a second portion of the power grid to a second voltage source;
coupling a second plurality of the support structures to the second portion of the power grid at spaced apart locations to receive the second voltage source.

19. The method according to claim 15, the memory die comprising a dynamic random access memory (DRAM) device.

20. (canceled)
